(19) United States
(12) Patent Application Publication
(10) Pub. No.: US 2026/0255501 A1
(43) Pub. Date: Aug. 27, 2026

(54) ELECTRICALLY CONNECTING A FLEXIBLE CIRCUIT TO A SUPPORT STRUCTURE

(71) Applicant: Teradyne, Inc., North Reading, MA (US)

(72) Inventors: David W. Lewinnek, Reading, MA (US); Madeline A. Scott, Milton, MA (US); Roger A. Plante, Chester, NH (US); Kenneth L. Degan, Hopkinton, MA (US); Alfred Zakarian, Concord, MA (US); Heng-Kit Too, Oak Park, CA (US)

(73) Assignee: Teradyne, Inc., North Reading, MA (US)

(21) Appl. No.: 19/065,545

(22) Filed: Feb. 27, 2025

(51) Int. Cl. H05K 3/36; H05K 3/00; H05K 3/34

(52) U.S. Cl. CPC H05K 3/363; H05K 3/0008; H05K 3/3485; H05K 2203/0169; H05K 2203/043; H05K 2203/1121

(57) ABSTRACT

An example method includes the following operations: depositing electrically conductive solder paste onto an electrically conductive surface of a flexible circuit while the flexible circuit is substantially flat; reflowing the solder paste to create solder bumps on the electrically conductive surface; applying flux to the solder bumps to produce an electrically conductive region; producing an assembly by bringing the electrically conductive region of the flexible circuit into contact with an electrically conductive surface of a structure that is at least partly non-flat; and heating the assembly to attach the electrically conductive surface of the flexible circuit to the electrically conductive surface of the structure.

### TECHNICAL FIELD

This specification describes example implementations of systems and processes for electrically connecting a flexible circuit to a non-flat support structure.

### BACKGROUND

Heretofore, flexible circuits were soldered using techniques involving robotic arms or other devices capable of soldering in three-dimensions. Small form factors and precision operation required of the robotic arms or other devices made using such techniques error prone and costly.

### SUMMARY

An example method includes the following operations: depositing electrically conductive solder paste onto an electrically conductive surface of a flexible circuit while the flexible circuit is substantially flat; reflowing the solder paste to create solder bumps on the electrically conductive surface; applying flux to the solder bumps to produce an electrically conductive region; producing an assembly by bringing the electrically conductive region of the flexible circuit into contact with an electrically conductive surface of a structure that is at least partly non-flat; and heating the assembly to attach the electrically conductive surface of the flexible circuit to the electrically conductive surface of the structure. The example method may include one or more of the following features either alone or in combination.

Heating the assembly may create a solder joint that electrically connects the electrically conductive surface of the flexible circuit and the electrically conductive surface of the structure. The solder joint may be able to pass in excess of 300 amperes (A) of current between the flexible circuit and the structure. A thickness of a solder bump may be 50% or less of a thickness of the solder paste on the surface of the flexible circuit while the flexible circuit is substantially flat.

Depositing the electrically conductive solder paste may include depositing the electrically conductive solder paste onto multiple electrically conductive surfaces of the flexible circuit while the flexible circuit is substantially flat. Reflowing the solder may create solder bumps on each of the multiple electrically conductive surfaces. The flux may be applied to the solder bumps on each of the multiple electrically conductive surfaces to produce multiple electrically conductive regions. The assembly may be produced by bringing each of the multiple electrically conductive regions of the flexible circuit into contact with a respective electrically conductive surface of the structure that is at least partly non-flat. Heating the assembly may attached each of the electrically conductive surfaces of the flexible circuit to a respective electrically conductive surface of the structure.

The multiple electrically conductive regions may include two electrically conductive regions. The structure may include a flexure component and a bracket. One of the multiple electrically conductive regions may be brought into contact with an electrically conductive surface of the flexure component and one of the multiple electrically conductive regions may be brought into contact with an electrically conductive surface of the bracket. The bracket may be substantially L-shaped.

At least part of the structure may be in contact with a mandrel having a shape that is based on an expected use of the assembly. Producing the assembly may include wrapping at least part of the flexible circuit around at least part of the structure in contact with the mandrel. Producing the assembly may include applying a clamp to one side of an area where the electrically conductive region of the flexible circuit is in contact with the electrically conductive surface of the structure.

Producing the assembly may include wrapping at least part of the flexible circuit around at least part of the structure. Producing the assembly may include applying clamps to both sides of an area where the electrically conductive region of the flexible circuit is in contact with the electrically conductive surface of the structure.

The operations may include electrically connecting the assembly to a printed circuit board (PCB). The operations may include electrically connecting the PCB with the assembly to a device interface board (DIB). The DIB may be for holding devices to test. The DIB may have a first signal pitch. One or more test instruments may be configured to test the devices have a second signal pitch. The PCB may be for converting between the first signal pitch and the second signal pitch.

The operations may include electrically connecting the one or more test instruments to the PCB with the assembly. The second signal pitch may be greater than the first signal pitch.

Producing the assembly may be performed separately from the depositing, reflowing, applying, and heating operations.

Heating the assembly may create a solder joint that electrically connects the electrically conductive surface of the flexible circuit and the electrically conductive surface of the structure. The solder joint may be rectangular in shape, round in shape, star-shaped, or V-shaped.

An example test system includes a device interface board (DIB) configured to hold devices to test, with the DIB having a first signal pitch; one or more test instruments configured to send signals to, and to receive signals from, the devices on the DIB in order to test the devices, with the one or more test instruments having a second signal pitch that is different from first signal pitch; and a circuit board between DIB and the one or more test instruments, with the circuit board being configured to translate between the first signal pitch and the second signal pitch. The circuit board includes an assembly including a flexible circuit and a structure. The flexible circuit includes an electrically conductive surface. The structure includes an electrically conductive surface. The electrically conductive surface of the flexible circuit is electrically connected to the electrically conductive surface of the structure by a solder joint. The solder joint includes melted solder bumps and flux.

The second signal pitch may be greater than the first signal pitch.

Any two or more of the features described in this specification, including in this summary section, may be combined to form implementations not specifically described in this specification.

At least part of the devices, systems, and processes described in this specification may be configured or controlled by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, systems, and processes described in this specification may be configured or controlled using a computing system comprised of one or more processing devices and memory storing instructions that are executable by the one or more processing devices to perform various control operations. The devices, systems, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is a side view of an example flexible circuit.

FIG. 2 is a block diagram showing operations included in an example process for creating an assembly that includes the flexible circuit.

FIG. 3 is a perspective view of an example assembly created by the process.

FIG. 4 is a side view of an example flexible circuit containing solder paste.

FIG. 5 is a side view of an example flexible circuit containing solder bumps.

FIG. 6 is a side view of an example flexible circuit containing flux on the solder bumps.

FIG. 7 is a side view of an example flexible circuit partially connected to a support structure mounted on a mandrel.

FIG. 8 is a side view of an example flexible circuit connected to a support structure mounted on a mandrel.

FIG. 9 is a side view of an example flexible circuit connected to a support structure absent a mandrel.

FIG. 10 is a side view of an example flexible circuit connected to a support structure mounted on a mandrel following heating to create solder joints.

FIG. 11 is a perspective view of an example printed circuit board containing one or more instances of the assembly created by the process of FIG. 2.

FIG. 12 is a block diagram of an example test system that includes a pitch-translation interposer board containing one or more instances of the assembly created by the process of FIG. 2.

Like reference numerals in different figures indicate like elements.

### DETAILED DESCRIPTION

Described herein are examples of systems and processes for electrically connecting a flexible circuit to a non-flat support structure. The resulting assembly may be used in any context, but is described herein in the context of a test system. A test system includes one or more devices for testing electronic devices, referred to herein as a device under test (DUT). The DUT may be any type of electronic device such as, but not limited to, a radio frequency (RF) transceiver, a microprocessor, any type of integrated circuit (IC), amplifiers, active or passive circuit components, or the like.

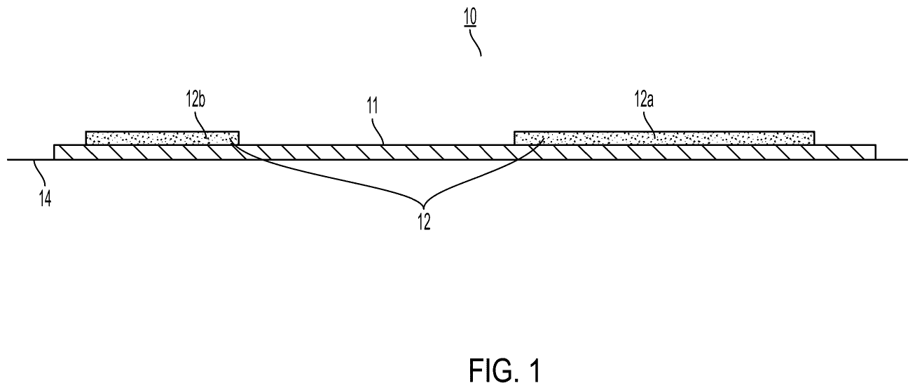

FIG. 1 shows an example of a flexible circuit 10. An example flexible circuit, also known as a “flex circuit”, is a type of electronic circuit that is configured to be flexible and bendable, allowing it to fit into compact and irregularly shaped spaces. These circuits may be made using a flexible plastic substrate 11, such as polyimide or polyester, which provide flexibility while enabling electrical connectivity to one or more electrically conductive surfaces 12 or other electrical devices on the flexible circuit. An electrically conductive surface includes an electrically conductive material such as copper that allows the flow of electric current. In this example, there are two electrically conductive surfaces 12a, 12b on flexible circuit board 10; however, flexible circuit may include three, four, five, or more electrically conductive surfaces. The electrically conductive surfaces may contain conductive traces or other electrical devices. The electrically conductive surfaces may be continuous, e.g., an entire strip of continuous conductivity within a region of the flexible circuit, or discontinuous, e.g., multiples spots of conductivity within a region of the flexible circuit.

Flexible circuits can incorporate a variety of electronic components onto their electrically conductive surfaces, such as resistors, capacitors, inductors, and integrated circuits, on the flexible substrate. The ability of flexible circuits, in some implementations, to bend and conform to different shapes without losing functionality may reduce the need for connectors and interconnecting wires in a design.

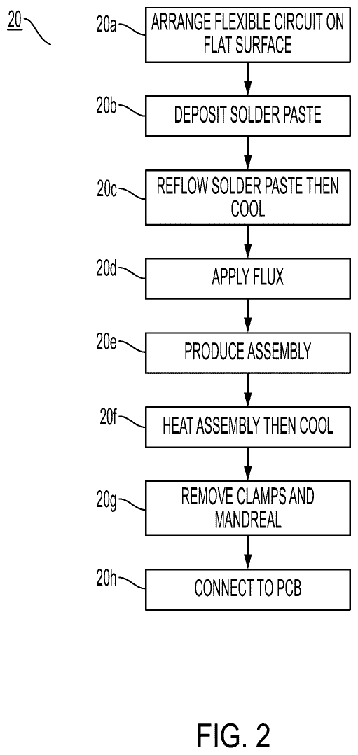

FIG. 2, shows examples of operations included in an example process 20 for electrically connecting flexible circuit 10 to a non-flat support structure.

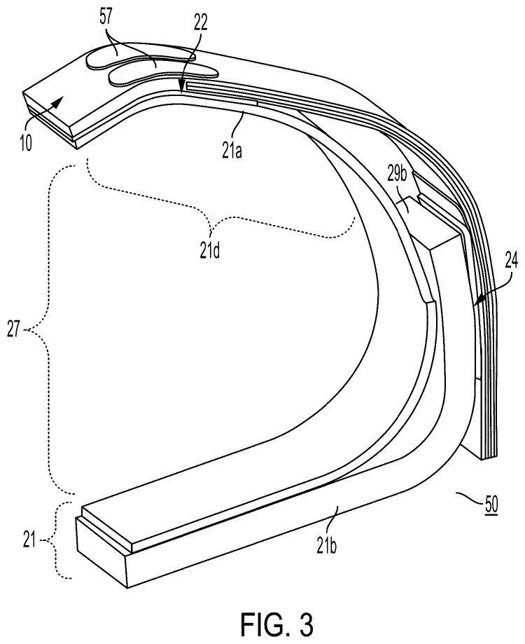

FIG. 3, which is described in more detail below, shows an example of a non-flat support structure 21 to which example flexible circuit 10 is electrically connected using electrically conductive solder joints 22, 24. In this example, structure 21 has a partially U-shape. However, process 20, and the systems that implement or are associated with process 20, may be used to electrically connect any flexible circuit to a support structure having any shape, including non-flat and flat support structures.

All or part of the operations included in process 20 may be controlled by or implemented by one or more computing systems. An example computing system may include a combination of hardware and software components that work together to control operations of process 20. The hardware components may include sensors, actuators, and controllers that monitor and adjust operational parameters. Computing systems may run machine learning algorithms and data analytics to predict adjust the process proactively, thereby increasing efficiency.

Referring also to FIG. 1, process 20 includes arranging (20a) flexible circuit 10 on a surface 14 that is flat or substantially flat (e.g., ±25% or less deviation from precisely flat). As a result, the flexible circuit is flat or substantially flat in shape. Flexible circuit 10 is arranged so that its electrically conductive surfaces 12a, 12b are face-up, meaning that they face away from surface 14.

In some implementations, a robotic arm (not shown) is used to arrange flexible circuit 10 on surface 14. An example process includes using robotic arm, equipped with end-effectors or grippers, picking up the flexible circuit from a stack or conveyor. The grippers may be designed with soft, non-abrasive materials to prevent damage to the flexible circuit. Once the flexible circuit is securely held, the robotic arm moves the flexible circuit to a designated placement area on surface 14. The robotic arm's movements may be controlled by a computer system (also referred to also as a control system) to ensure smooth and accurate positioning. The control system may control vision sensors or cameras to assist in placing the flexible circuit, compensating for any misalignments or variations in the circuit's shape. As the robotic arm positions the flexible circuit onto the surface, the robotic arm may lower the flexible circuit, ensuring that the flexible circuit lays flat without any creases or folds. In some implementations, throughout this operation, the robotic arm's control system may continuously monitor operation of the robotic arm, making real-time adjustments to ensure optimal handling and placement.

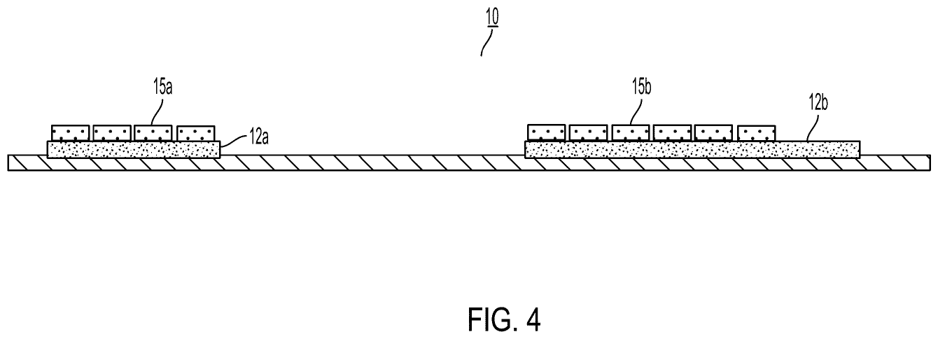

Referring also to FIG. 4, process 20 includes depositing (20b) electrically conductive solder paste 15a, 15b onto respective electrically conductive surfaces 12a, 12b of the flexible circuit while the flexible circuit is substantially flat.

Any appropriate type of electrically conductive solder paste may be deposited. Example types of solder paste that may be deposited in operation 20b include, but are not limited to, lead-based and lead-free solder pastes. Lead-based solder paste may be made from a tin-lead alloy. Lead-free solder paste may be made from a tin-silver-copper (SAC) alloy. The type of solder paste used may be based on requirements of the electronic devices on the flexible circuit and the solder joint to be made.

Depositing the electrically conductive paste may include printing the electrically conductive solder paste onto electrically conductive surfaces 12a, 12b of the flexible circuit or using any other appropriate deposition process. Printing the solder paste may be implemented using a stencil printing method, where a thin, custom-designed stencil with apertures matching the electrically conductive layout of the flexible circuit is aligned over the flexible circuit. To maintain the flexible circuit's shape and prevent deformation during printing, the flexible circuit may be supported on a flat vacuum table or specialized fixture(s) (not shown) that hold the flexible circuit flat and substantially immobile. A computer-controlled automated stencil printer may be used to print the solder paste. The robotic arm may lay a stencil (not shown) over the electrically conductive surfaces 12a, 12b, with the stencil containing one or more openings where solder is to be applied to each conductive surface. The automated stencil printer may use a squeegee to spread the solder paste across the stencil, ensuring that the solder paste fills any apertures in the stencil completely and is deposited onto the exposed electrically conductive surfaces of the flexible circuit. After printing, the stencil is removed (e.g., by a robotic arm), and the flexible circuit may be inspected to ensure the solder paste is applied uniformly and correctly before proceeding to component placement and reflow soldering. A computer controlled camera and image processing techniques may be used to perform the inspection automatically.

Operation 20b may be performed for/on a single conductive region on flexible circuit 10 or for/on multiple conductive regions of flexible circuit 10.

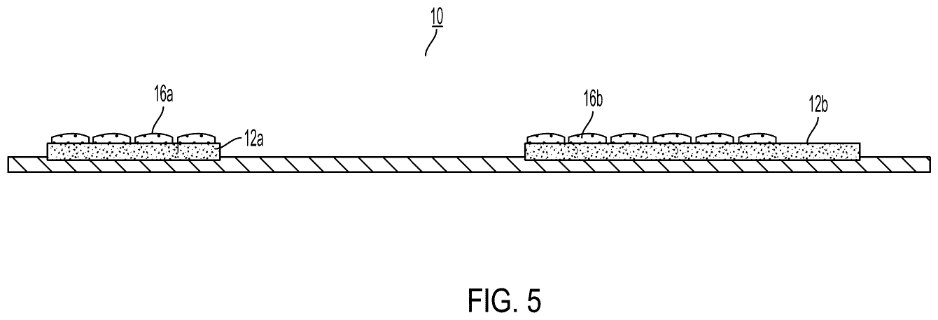

Referring also to FIG. 5, process 20 includes reflowing (20c) the solder paste 15a, 15b of FIG. 4 deposited on the flexible circuit to create solder bumps 16a, 16b on the electrically conductive surface 12a, 12b of the flexible circuit 10. An example reflowing technique includes transferring the flexible circuit with the solder paste printed thereon to a reflow oven (not shown), where the flexible circuit undergoes one or more controlled heating cycles. Transfer may be implemented using a robotic arm, like that described above or using any other appropriate techniques.

In an example implementation, the robotic arm picks-up the flexible circuit from its previous processing station, e.g., surface 14. The robotic arm may use movements controlled by its control system to ensure the flexible circuit is held securely and without bending or folding. The robotic arm and/or control or computing system may incorporate vision sensors or cameras to verify the correct alignment and orientation of the circuit before proceeding. Once the flexible circuit is securely grasped, the robotic arm transports the flexible circuit to an entrance of the reflow oven. The arm's movements may be smooth and controlled, controlling any vibrations or sudden motions that could affect the integrity of the flexible circuit or the applied solder paste. As the robotic arm approaches the reflow oven, the robotic arm may align the flexible circuit with a belt or entry mechanism of the reflow oven. The robotic may then place the flexible circuit onto the conveyor or entry mechanism, ensuring that the flexible circuit is positioned correctly for the reflow process. The robotic arm's control system may, in some examples, continuously monitors this process, making real-time adjustments as needed to maintain accuracy and prevent any mishandling.

The reflow oven is programmed by the computing system to move the flexible circuit with the solder paste printed thereon (e.g., using a conveyer) to an interior of the reflow oven. The reflow oven is programmed, e.g., by the computing system to follow a specific temperature profile, which may include preheating, soaking, reflow, and cooling stages. In this example, during the reflow stage, the temperature is raised above the melting point of the solder paste, causing solder particles to melt and coalesce into substantially uniform (e.g., spherical) bumps. The flexible circuit may be removed from the reflow oven and placed back at the solder paste application area at surface 14, e.g., using the robotic arm in a process inverse to that described above, where the flexible circuit cools. The solder, now solder bumps, solidifies. Defects, such as voids or non-uniform bumps, can lead to poor connections and potential failures in the final product. Therefore, control of the reflow process parameters and inspection of the solder bumps may be implemented to achieve desired results. Inspection may be performed automatically using computer-controlled cameras and image processing.

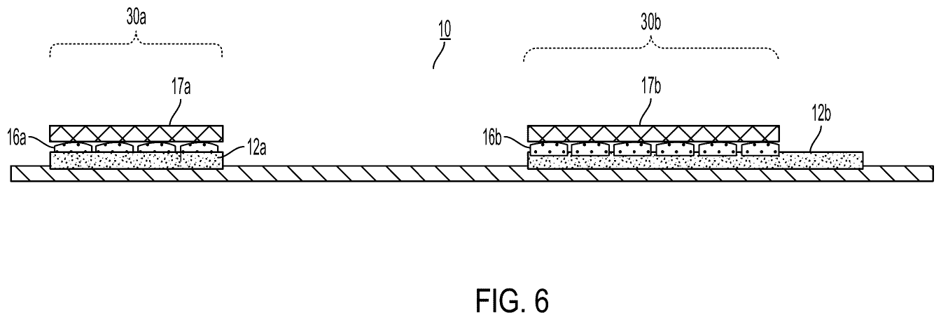

Referring also to FIG. 6, process 20 includes applying (20d) flux 17a, 17b to the respective cooled solder bumps 16a, 16b to produce electrically conductive regions. Flux is a chemical agent used in the soldering process to facilitate the joining of metal surfaces by promoting wetting and adhesion of the solder. Flux performs several functions, including the removal of oxides and impurities from the metal surfaces, which can otherwise inhibit the formation of strong, reliable solder joints. Flux also helps to prevent the re-oxidation of these surfaces during the soldering process by creating a protective barrier. Various types of flux may be applied including rosin-based, water-soluble, and no-clean fluxes, each suited to different applications and cleaning requirements. The choice of flux depends on the requirements of the soldering process, the materials being joined, and the desired properties of the final assembly.

The application of the flux may use a precise dispensing method, such as spraying, dipping, or using a flux pen, to ensure an even and controlled coating over the solder bumps. Application of flux may use a stencil. An example technique involves placing one or more stencils, which may be custom-designed with apertures that align with the solder bumps on the flexible circuit, over the cooled solder bumps. The stencil acts as a mask, allowing flux to be applied only to the desired areas. Once the stencil is aligned, flux is spread across its surface using a squeegee or similar tool, ensuring that the flux is deposited through the apertures onto the solder bumps below. A robotic arm as described above may be used to place the stencil(s) and an automated stencil printer such as that described above may be used to apply the flux.

Operation 20d may be performed for/on a single conductive region on flexible circuit 10 or for/on multiple conductive regions of flexible circuit 10.

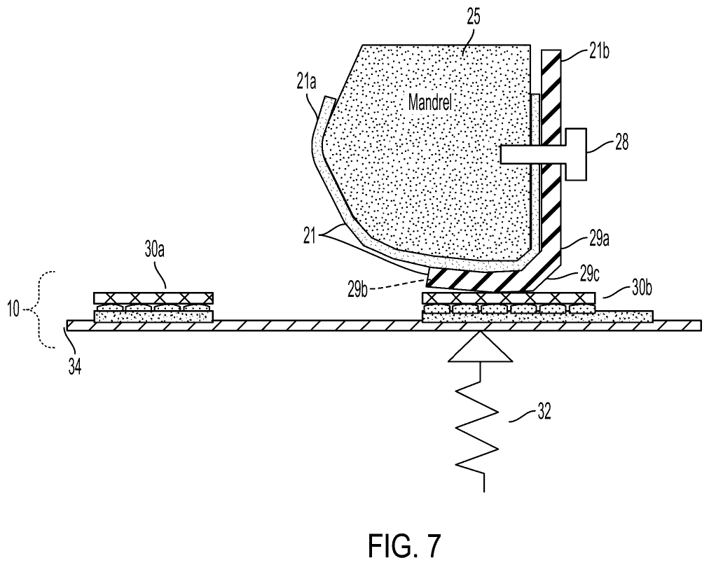

Referring to FIGS. 3 and 7, in some implementations, support structure 21, comprised of a flexure component 21a and a bracket 21b in this example, may be connected to a mandrel 25. A mandrel is tool used in various manufacturing and machining processes to support, shape, or hold workpieces. The mandrel may be made of a rigid material, such as metal or rigid polymer. Mandrel 25 has a shape that is substantially complementary to the shape of the interior 27 (FIG. 3) of support structure 21 such that the mandrel can support the support structure during process 20. As shown in FIG. 7, in some implementations support structure 21 may be attached to mandrel 25 using, for example, one or more fasteners 28 such as screws or bolts.

In this example, support structure 21 is at last partly rigid and at least partly flexible (but less flexible than the flexible circuit 10). In some implementations, all of the support structure may be rigid or all of the support structure may be flexible. The size and shape of the support structure and the mandrel may be based on the desired size and shape of the assembly to be created from the support structure and flexible circuit.

Example flexure component 21a is a curved mechanical element configured to provide controlled flexibility and movement in various applications, such connecting to a printed circuit board. An example flexure component may be fabricated from high-strength metals like copper or stainless steel, which offer fatigue resistance and durability. The design of the flexure component allows for elastic deformation/flexibility under load while maintaining structural integrity. This controlled deformation enables the flexure component to accommodate displacements with repeatability.

Example bracket 21b may be substantially “L” shaped, referred to as an “L bracket”. An example L bracket may be formed of rigid material(s) such as copper or stainless steel. In this example, the L bracket is designed in the shape of an “L,” with substantially perpendicular arms 29a, 29b at about a 90° (e.g., ±25%) angle to each other. Example L bracket has another arm 29c that connects these perpendicular arms. Other types of brackets, L-shaped or not, may be part of support structure 21. In some implementations, bracket 21b may be a flexure component as well.

As shown in FIG. 3, flexure component 21a is combined with—for example attached to or integrally formed with—bracket 21b. For example, flexure component and bracket 21b may be welded together, fasted together using one or more fasteners such as bolts or screws, or attached using other mechanisms. Referring also to FIG. 3, in this example, flexure component 21a is fixed to, and within, the interior of the bracket 21b. Flexure component 21a and bracket 21b are attached to each other such that part 21d of flexure component 21a extends beyond shorter arm 29b of bracket 21b and curves away from shorter arm 29b in the direction of longer arm 21b. Flexure component 21a being fixed within bracket 21b combines the structural support of the bracket with the repeatable movement capabilities of the flexure component.

In some implementations, both flexure component 21a and bracket 21b may be electrically conductive, and thus each may be used to make a connection between two electrical devices or printed circuit boards (PCBs). For example, the entirety of flexure component 21a and bracket 21b may be electrically conductive or flexure component and bracket 21b may each contain electrically conductive regions on respective non-conductive flexible or rigid substrates. An example PCB is made from a non-conductive substrate, such as fiberglass-reinforced epoxy laminate. The PCB features a pattern of conductive pathways etched or printed onto its surface. These pathways form circuits that electrically connect to the flexible circuit and/or support structure.

Referring also to FIGS. 2 and 7, process 20 includes producing (20e) an assembly by bringing the electrically conductive regions 30a, 30b of the flexible circuit, which now include solder bumps with the flux applied thereto, into contact with electrically conductive surfaced of support structure 21.

As shown in FIG. 7, in this example, the support structure 21 supported by the mandrel may be moved into contact with conductive region 30b of flexible circuit 10. In some implementations, this may be done manually or using a robotic arm. For example, a robotic arm may be controlled by the computing system bring the support structure 21 supported by the mandrel into contact with the flexible circuit. For example, a robotic arm, equipped with grippers designed to grip the support structure and mandrel, moves the support structure and mandrel from an initial position. The arm's movements are controlled by the computing system, which may utilize vision sensors or cameras to ensure the correct orientation and alignment of bracket arm 29b to conductive region 30b. In this example, as the arm approaches the flexible circuit, the arm maneuvers the support structure and mandrel into position, ensuring that the conductive region 30b of the flexible circuit aligns with intended conductive surfaces of the support structure including the flexure component and bracket. In the example of FIG. 7, conductive region 30b of the flexible circuit aligns to a conductive surface of backet 21b and conductive region 30a of the flexible circuit will align to a conductive surface of flexure component 21a when the flexible circuit is wrapped around the support structure as described below. The robotic arm may be controlled to press the bracket 21b against conductive region 30b of the flexible circuit, applying sufficient pressure to ensure that the two do not move during subsequent operations.

After bracket 21b is in contact with flexible circuit 10, in some implementations, one or more clamps 32 may be applied, for example where the solder bumps on the flexible circuit 10 are located, to ensure contact between the solder bumps and the bracket 21b or conductive surfaces thereof. An example type of clamp that may be used includes a binder clamp or a bar clamp. An example bar clamp includes bar with a fixed jaw at one end and an adjustable jaw that slides along the bar to accommodate different sizes of workpieces. The adjustable jaw may be tightened using a screw mechanism, allowing for control over the clamping pressure. An example binder clamp includes a metal clip with two flat metal arms connected by a flexible steel spring. The arms can be squeezed together to open the clip, allowing it to grip. Once released, the spring tension holds the two elements being clamped in place.

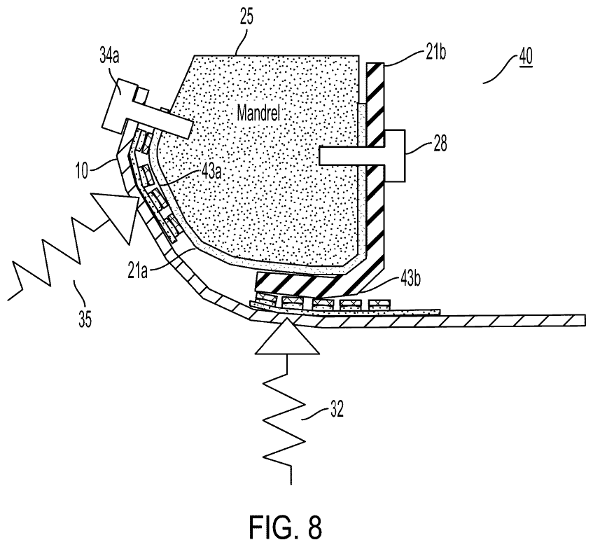

Referring to FIG. 8, in this example, the flexible circuit 10 may be brought into contact with the flexure component 21a of the support structure while the support structure is supported by the mandrel 25. The flexibility of the flexible circuit 10 allows the flexible circuit to conform to the shape of flexure component, as shown.

In some implementations, the flexible circuit 10 may be brought into contact with the flexure component 21a manually or using a robotic arm. For example, a robotic arm, equipped with grippers designed to handle flexible circuits, picks-up an end 34 (FIG. 7) of flexible circuit 10 from its flat position. The arm's movements are controlled by the computing system, which may utilize vision sensors or cameras to ensure the correct orientation and alignment of the flexible circuit with the flexure component and bracket of the support structure. In this example, as the arm approaches the support structure, the arm maneuvers the flexible circuit into position, ensuring that the conductive region of the flexible circuit aligns with intended conductive surface flexure component 21a. The support structure and mandrel are kept stationary during this positioning. In the example of FIG. 7, conductive region 30a of the flexible circuit aligns to a conductive of flexure component 21a. The robotic arm may be controlled to press the flexible circuit against the flexure component.

After the flexible circuit is in contact with the flexure component, in some implementations, the flexible circuit may be attached to the flexure component part of the support structure. For example, as shown in FIG. 8, a fastener 34a, such as a screw or bolts may be applied to fix flexible circuit 10 to support structure 21 and, in some cases, also to mandrel 25. One or more clamps 35 may also be applied to the resulting assembly, for example, where the solder bumps on the flexible circuit 10 are located, to ensure contact between the solder bumps and flexure component 21a or conductive surfaces thereof. A bar clamp or other type of clamp may be used.

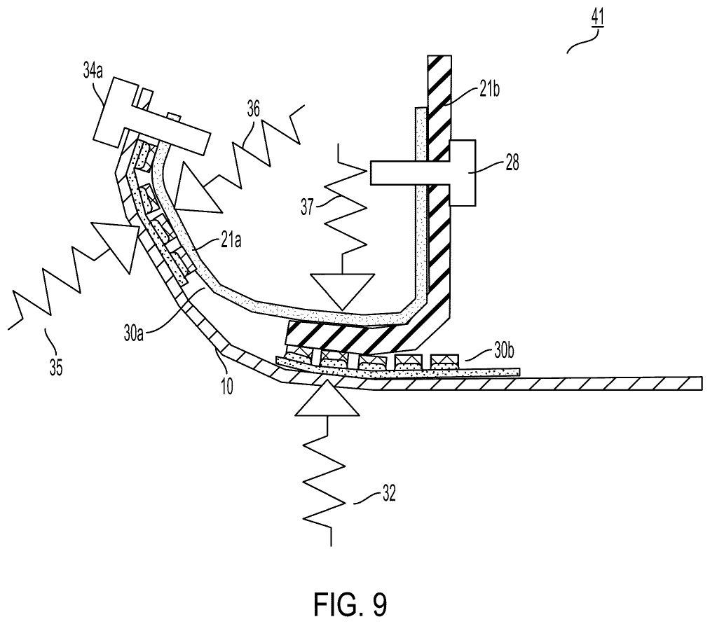

Referring to FIG. 9, in some implementations, the mandrel 25 may be omitted. In such implementations, the foregoing operations may be performed, except that clamps 32, 35, 36, 37 may be applied to the flexible circuit 10 and to the flexure component 21a. Bar clamps or other types of clamps may be used.

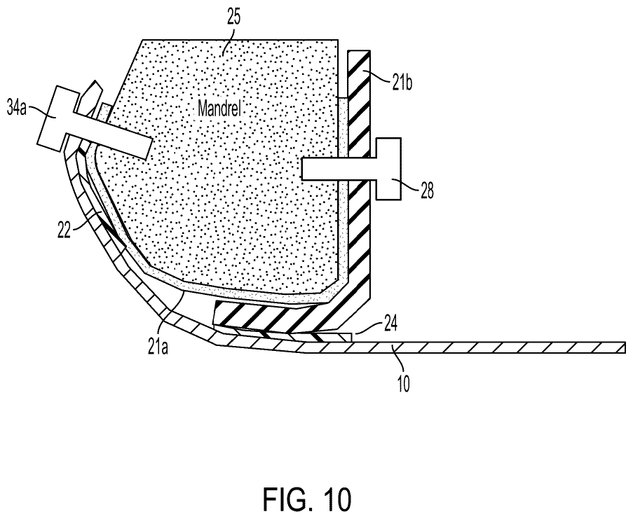

Referring also to FIG. 2, after an assembly, such assembly 40 of FIG. 8 or assembly 41 of FIG. 9 is constructed, the assembly is heated (20f) to attach the electrically conductive surface(s) of the flexible circuit to the electrically conductive surface(s) of the support structure. The process of heating to cause the solder bumps with flux to melt and form a connection with the conductive surfaces of the bracket and flexure component may be performed in reflow oven. For example, as above, a robotic arm may bring the assembly to the reflow oven as described above. The assembly may be subjected to controlled heat in the reflow oven, where the temperature may be ramped up to melt the solder bumps. As the solder melts, it forms a metallurgical bond with conductive surfaces (e.g., 43a, 43b (FIG. 8)) of the bracket and the flexure component creating, at ambient temperature (e.g., about 20° to 25° Celsius) electrical and mechanical connections between the flexible circuit and the flexure component and between the flexible circuit and the bracket; in other words creating electrical and mechanical connections between the flexible circuit and the support structure. The electrical and mechanical connections may each be referred to as a solder joint, examples of which are solder joints 22 and 24 of FIG. 3, which are also shown in FIG. 10. Thereafter, the assembly may be removed from the reflow oven, e.g., using a robotic arm, and left to cool. Following cooling, the mandrel and/or clamps may be removed (20g) from the support structure, either manually or robotically, as shown in FIG. 3.

In some implementations, a thickness of a solder bump is less than a thickness of the solder paste on the surface of the flexible circuit while the flexible circuit is substantially flat. In some implementations, a thickness of a solder bump is 50% or less of a thickness of the solder paste on the surface of the flexible circuit while the flexible circuit is substantially flat. The solder joint may have sufficient electrical conductivity and mechanical stability to pass in excess of 300 amperes (A) of current between the flexible circuit and the support structure. The solder joint may have sufficient electrical conductivity and mechanical stability to pass in excess of 200A of current between the flexible circuit and the support structure. This includes current passed from the flexible circuit to the support structure and from the support structure to the flexible circuit. The solder joint that is created may have any shape. In some examples, the solder joint may be rectangular in shape, round in shape, star-shaped, or V-shaped. The shape of the solder joint may be based, for example, on the shape of the stencil used to apply the solder and flux.

Solder bumping allows for blind mating of two surfaces, facilitating the assembly of two solderable surfaces with reduced involvement of additional processes, even in complex configurations, as long as they can be held together (e.g., clamped) in 3D space. Reflow soldering addresses thermal mass concerns and reduces the time required for soldering, especially when dealing with a larger numbers of solder joints.

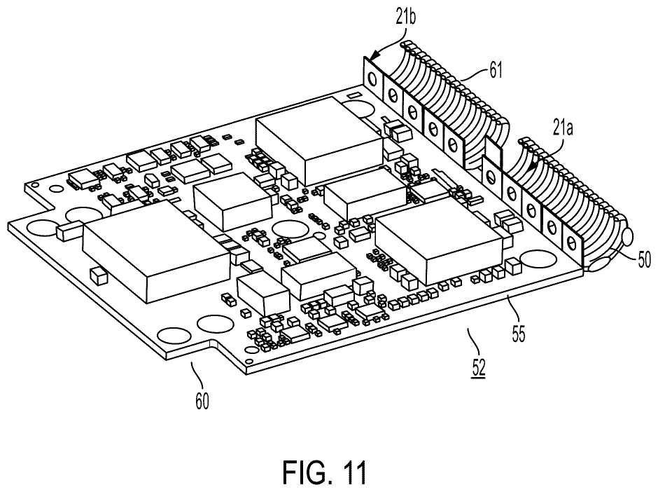

Referring to FIG. 11, one or more instances of example assembly 50 may be used to create an electrical connection to a PCB. PCB 52 may have any functionality. For example, PCB 52 may be interposer board that changes signal pitch. Signal pitch refers to the distance between the centers of adjacent electrical conductors or signal paths, such as pins, pads, or traces, on a circuit board or electronic component. It is a parameter in the design and manufacturing of electronic devices, as it influences the density and arrangement of connections within a system. A smaller signal pitch allows for more connections in a given area, enabling the creation of compact and high-density electronic assemblies. Conversely, a larger signal pitch may simplify manufacturing and reduce interference but limit miniaturization.

An interposer board changes signal pitch to adapt the spacing (pitch) of electrical signals between two different components or systems. The interposer board acts as an intermediary layer, featuring conductive traces that reroute signals from one pitch to another. For example, it can connect one or more fine-pitch connections to a PCB having a coarser pitch. The interposer board may be designed to ensure little or no signal loss and to maintain electrical performance. The interposer board may include features such as vias, pads, and solder bumps to facilitate the connection process,

Process 20 may include electrically connecting (20h) assembly 50 to PCB 52. For example, the flexible circuit 10 may electrically connect to one or more layers (not shown) of the PCB. The support structure may provide support for the assembly against the substrate 55 of the PCB and electrical connections to components thereof. The flexure component may expose electrically conductive elements—such as electrically conductive surfaces 57 (FIG. 3)—on the other side of the flexible circuit to enable electrical connection of the flexible circuit to another device or PCB. For example, PCB 52 may be electrically connected at one end 60 to a test instrument, such as those described below and at the other end 61 to a device interface board (DIB). A DIB circuit board is configured to enable the testing and evaluation of electronic devices during the development and manufacturing process. This board serves as a an intermediary between the DUT and test instrument(s), providing the necessary connections and signal conditioning to ensure accurate and efficient testing.

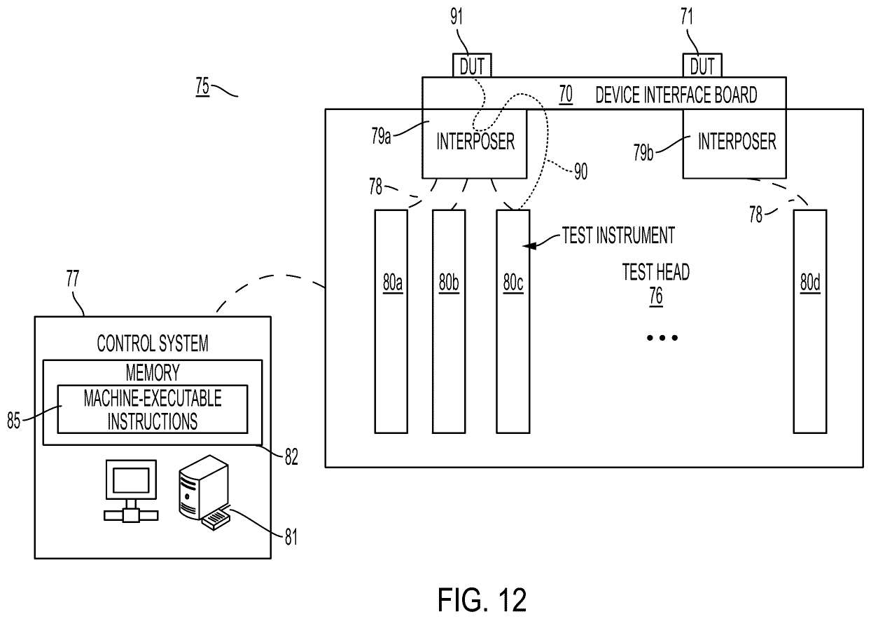

FIG. 12 shows components of example automatic test equipment (ATE) 75 that may be an example implementation of, or include components of, a tester. ATE 75 includes a test head 76, DIB 70, and an external control system 77, which may be a control system, or portion thereof, that is external to the test head or module.

DIB 70 is connected to test head 76 and includes mechanical and electrical interfaces to one or more DUTs, such as DUT 71, that are being tested or are to be tested by the ATE. An interposer board 79a, such as PCB 52 (FIG. 11) containing assembly 50, electrically connects to DIB 70 via the flexible circuit 10 on flexure component 21a. The interposer board in this example, translates wider or coarse pitch signals from one or more test instruments to finer or narrower pitch signals for the DIB and vice versa.

In some implementations, a test instrument 80c may send signals via a path 90 directly to DIB 70. Path 90 may then pass through interposer board 79a, where the pitch of those signals are changed and the resulting signals, with pitch changed, are then applied back to the DIB and ultimately, to DUT 91.

The test instruments include hardware devices, each of which may include one or more processing devices, pin electronics, programmable logic such as an FPGA, and memory. Test instruments 80a to 80d may execute the test programs to test DUTs held on the DIB, including sending test signals to the DUT and receiving response signals from the DUT. These signals 78 pass through one or more interposer boards 79a, 79b. Although only four test instruments are shown, the ATE 75 may include any number of test instruments, including those residing outside of test head 76. Signals, including RF (radio frequency), DC (direct current), and digital signals, may be sent to, and received from, the DUT over multiple test channels or other electrically conductive media.

Control system 77 may communicate with components included in the test head to control testing. For example, control system 77 may download test program sets to test instruments 80a, 80b, 80c, and 80d in the test head. In an example, a test program generates a test pattern (or flow) to provide signals to the DUT for testing and/or to control the DUT to output RF signals to the modules. The test pattern may be written to output test signals to elicit a response from the DUT. A test instrument or the control system may analyze the response to determine if the DUT passed or failed testing.

In some implementations, all or part of the control functionality attributed to control system 77 may also or instead be implemented on a test instrument and/or all or part of the testing functionality attributed to one or more test instruments may also or instead be implemented on control system 77. In some implementations, at least part of the control functionality may be distributed across processing device(s) 81 and one or more of test instruments 80a to 80d. Processing device(s) 81 may execute instructions 85 stored in memory 82 to perform control functions.

In some implementations, at least operations 20a, 20b, 20d, 20e, 20g, and 20h, along with moving the flexible circuit and assembly may be performed manually.

In some implementations, flexure 21a and bracket 21b are not electrically conductive. For example, they may be made of a non-conductive material, such as a polymer, or a minimally conductive metal such as titanium. In some implementations, flexure 21a and bracket 21b may covered in a shielding layer, which may be a material that is not electrically conductive or minimally electrically conductive. In such implementations, the solder bumps 16a, 16b may make a purely mechanical connection between the flex circuit and the flexure and bracket. This enables use of the flex circuit as a type of low-impedance interposer, connecting the electrical pads on the DIB with the electrical pads at the outside tip of the flex circuit.

All or part of the systems and processes described herein including but not limited to process 20 and variants thereof may be configured and/or controlled at least in part by one or more processing devices using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected.

Actions associated with configuring or controlling the test system and processes described herein can be performed by one or more programmable processors executing one or more computer programs to control or to perform all or some of the operations described herein. All or part of the test systems and processes can be configured or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

As used herein, the terms “comprises,” “comprising,” “includes,” “including,” “has,” “having,” “contains,” “containing,” and any variations thereof, are intended to cover a non-exclusive inclusion, such that systems, techniques, apparatus, support structures, processes, or other subject matter described or claimed herein that includes, has, or contains an element or list of elements does not include only those elements but can include other elements not expressly listed or inherent to such systems, techniques, apparatus, support structures, processes or other subject matter described or claimed herein.

All examples described herein are non-limiting.

In the description and claims provided herein, the adjectives “first”, “second”, “third”, and the like do not designate priority or order unless context suggests otherwise. Instead, these adjectives may be used solely to differentiate the nouns that they modify.

Any mechanical or electrical connection herein may include a direct physical connection or an indirect physical connection that includes one or more intervening devices unless context suggests otherwise. A connection between two electrically conductive devices includes an electrical connection unless context suggests otherwise. The signals described herein are electrical signals unless context suggests otherwise.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. A method comprising:
depositing electrically conductive solder paste onto an electrically conductive surface of a flexible circuit while the flexible circuit is substantially flat;
reflowing the solder paste to create solder bumps on the electrically conductive surface;
applying flux to the solder bumps to produce an electrically conductive region;
producing an assembly by bringing the electrically conductive region of the flexible circuit into contact with an electrically conductive surface of a structure that is at least partly non-flat; and
heating the assembly to attach the electrically conductive surface of the flexible circuit to the electrically conductive surface of the structure.

2. The method of claim 1, wherein heating the assembly creates a solder joint that electrically connects the electrically conductive surface of the flexible circuit and the electrically conductive surface of the structure.

3. The method of claim 2, wherein the solder joint is able to pass in excess of 300 amperes (A) of current between the flexible circuit and the structure.

4. The method of claim 2, wherein a thickness of a solder bump is less than a thickness of the solder paste on the surface of the flexible circuit while the flexible circuit is substantially flat.

5. The method of claim 2, wherein a thickness of a solder bump is 50% or less of a thickness of the solder paste on the surface of the flexible circuit while the flexible circuit is substantially flat.

6. The method of claim 1, wherein:
depositing the electrically conductive solder paste comprises depositing the electrically conductive solder paste onto multiple electrically conductive surfaces of the flexible circuit while the flexible circuit is substantially flat;
wherein reflowing the solder creates solder bumps on each of the multiple electrically conductive surfaces;
wherein the flux is applied to the solder bumps on each of the multiple electrically conductive surfaces to produce multiple electrically conductive regions;
wherein the assembly is produced by bringing each of the multiple electrically conductive regions of the flexible circuit into contact with a respective electrically conductive surface of the structure that is at least partly non-flat; and
wherein heating the assembly attaches each of the electrically conductive surfaces of the flexible circuit to a respective electrically conductive surface of the structure.

7. The method of claim 6, wherein the multiple electrically conductive regions are two electrically conductive regions.

8. The method of claim 6, wherein the structure comprises a flexure component and a bracket; and
wherein one of the multiple electrically conductive regions is brought into contact with an electrically conductive surface of the flexure component and one of the multiple electrically conductive regions is brought into contact with an electrically conductive surface of the bracket.

9. The method of claim 8, wherein the bracket is substantially L-shaped.

10. The method of claim 1, wherein at least part of the structure is in contact with a mandrel having a shape that is based on an expected use of the assembly; and
wherein producing the assembly comprises wrapping at least part of the flexible circuit around at least part of the structure in contact with the mandrel.

11. The method of claim 10, wherein producing the assembly comprises applying a clamp to one side of an area where the electrically conductive region of the flexible circuit is in contact with the electrically conductive surface of the structure.

12. The method of claim 1, wherein producing the assembly comprises wrapping at least part of the flexible circuit around at least part of the structure.

13. The method of claim 12, wherein producing the assembly comprises applying clamps to both sides of an area where the electrically conductive region of the flexible circuit is in contact with the electrically conductive surface of the structure.

14. The method of claim 1, further comprising:
electrically connecting the assembly to a printed circuit board (PCB).

15. The method of claim 14, further comprising:
electrically connecting the PCB with the assembly to a device interface board (DIB), the DIB for holding devices to test, the DIB having a first signal pitch;
wherein one or more test instruments to test the devices have a second signal pitch, the PCB for converting between the first signal pitch and the second signal pitch.

16. The method of claim 15, further comprising:
electrically connecting the one or more test instruments to the PCB with the assembly, the second signal pitch being greater than the first signal pitch.

17. The method of claim 1, wherein producing the assembly is performed separately from the depositing, reflowing, applying, and heating operations.

18. The method of claim 1, wherein heating the assembly creates a solder joint that electrically connects the electrically conductive surface of the flexible circuit and the electrically conductive surface of the structure, the solder joint being rectangular in shape, round in shape, star-shaped, or V-shaped.

19. A test system comprising:
a device interface board (DIB) configured to hold devices to test, the DIB having a first signal pitch;
one or more test instruments configured to send signals to, and to receive signals from, the devices on the DIB in order to test the devices, the one or more test instruments having a second signal pitch that is different from first signal pitch; and
a circuit board between DIB and the one or more test instruments, the circuit board being configured to translate between the first signal pitch and the second signal pitch, the circuit board comprising:
an assembly comprising a flexible circuit and a structure, the flexible circuit comprising an electrically conductive surface, the structure comprising an electrically conductive surface, the electrically conductive surface of the flexible circuit being electrically connected to the electrically conductive surface of the structure by a solder joint, the solder joint comprising melted solder bumps and flux.

20. The test system of claim 19, wherein the second signal pitch is greater than the first signal pitch.
